(19) United States
(12) Patent Application Publication
(10) Pub. No.: US 2026/0333687 A1
(43) Pub. Date: Oct. 22, 2026

(54) CELL STRUCTURE OF THIRD GENERATION EMBEDDED SUPER FLASH MEMORY AND METHOD OF FORMING THE SAME

(71) Applicant: United Microelectronics Corp., Hsinchu (TW)

(72) Inventor: Xiaoli Wang, Singapore (SG)

(73) Assignee: United Microelectronics Corp., Hsinchu (TW)

(21) Appl. No.: 19/204,636

(22) Filed: May 12, 2025

(30) Foreign Application Priority Data
Apr. 16, 2025 (TW) 114114331

(51) Int. Cl. H10B 41/30; G11C 5/06; H10D 30/68

(52) U.S. Cl. CPC H10B 41/30; G11C 5/063; H10D 30/6892

(57) ABSTRACT

A cell structure of a third generation embedded super flash memory and a method of forming the same are provided. The cell structure of the third generation embedded super flash memory includes a source line located in a substrate; and a first memory stack, a second memory stack, and an erase gate located above the substrate. The first memory stack includes a first floating gate and a first control gate located above the first floating gate. The second memory stack includes a second floating gate and a second control gate located above the second floating gate. The erase gate is located between the first memory stack and the second memory stack, and is located above the source line. The erase gate has the same width in a first horizontal direction, and the erase gate is disconnected between two adjacent bit lines.

### CROSS-REFERENCE TO RELATED APPLICATION

This application claims the priority benefit of Taiwan application serial no. 114114331 filed on Apr. 16, 2025. The entirety of the above-mentioned patent application is hereby incorporated by reference herein and made a part of this specification.

### BACKGROUND

### Technical Field

The disclosure relates to a cell structure of a third generation embedded SuperFlash® (ESF3) memory, and more particularly to a cell structure of a third generation embedded SuperFlash® (ESF3) memory and a method of forming the same.

### Description of Related Art

In the structure of the third generation embedded SuperFlash® (ESF3) of silicon storage technology (SST), two adjacent bit lines share one erase gate (EG), and the erase gates (EG) of each bit in an adjacent word line (WL) are interconnected.

However, if an erase voltage of a certain bit is abnormal, the erase voltage of each bit in the adjacent word line will also become abnormal.

Such a situation complicates failure analysis (FA) and makes it difficult to accurately determine the specific location of a defect, which poses a major challenge to failure analysis.

### SUMMARY

The disclosure provides a cell structure of a third generation embedded super flash memory and a method of forming the same to facilitate subsequent failure analysis (FA) analysis.

An embodiment of the disclosure provides a cell structure of a third generation embedded super flash memory, which includes a source line located in a substrate; and a first memory stack, a second memory stack, and an erase gate located above the substrate. The first memory stack includes a first floating gate and a first control gate located above the first floating gate. The second memory stack includes a second floating gate and a second control gate located above the second floating gate. The erase gate is located between the first memory stack and the second memory stack and is located above the source line. The erase gate has a same width in a first horizontal direction, and the erase gate is disconnected between two adjacent bit lines.

In some embodiments, a width of the first floating gate in the first horizontal direction is greater than a width of the first control gate in the first horizontal direction.

In some embodiments, a width of the second floating gate in the first horizontal direction is greater than a width of the second control gate in the first horizontal direction.

In some embodiments, the first memory stack further includes a first inter-gate dielectric layer between the first floating gate and the first control gate.

In some embodiments, the second memory stack further includes a second inter-gate dielectric layer between the second floating gate and the second control gate.

In some embodiments, a first inner spacer and a first outer spacer on a sidewall of the first memory stack are further included.

In some embodiments, the first inner spacer is silicon oxide or silicon oxide-silicon nitride-silicon oxide.

In some embodiments, the first outer spacer is a high temperature oxide.

In some embodiments, a second inner spacer and a second outer spacer on a sidewall of the second memory stack are further included.

In some embodiments, the second inner spacer is silicon oxide or silicon oxide-silicon nitride-silicon oxide.

In some embodiments, the second outer spacer is a high temperature oxide.

In some embodiments, a first word line and a second word line located above the substrate are further included. The first word line is between the first memory stack and the bit line, and the second word line is between the second memory stack and the bit line.

An embodiment of the disclosure provides a method of forming a cell structure of a third generation embedded super flash memory, which includes the following steps. A first memory stack and a second memory stack are formed above a substrate. The first memory stack sequentially includes a first floating gate, a first inter-gate dielectric layer, a first control gate, and a first hard mask in a vertical direction. A width of the first floating gate in a first horizontal direction perpendicular to the vertical direction is greater than a width of the first inter-gate dielectric layer, the first control gate, and the first hard mask in the first horizontal direction. The second memory stack sequentially includes a second floating gate, a second inter-gate dielectric layer, a second control gate, and a second hard mask in the vertical direction. A width of the second floating gate in the first horizontal direction perpendicular to the vertical direction is greater than a width of the second inter-gate dielectric layer, the second control gate, and the second hard mask in the first horizontal direction. A first inner spacer is respectively formed on sidewalls of the first inter-gate dielectric layer, the first control gate, and the first hard mask, and a second inner spacer is respectively formed on sidewalls of the second inter-gate dielectric layer, the second control gate, and the second hard mask. A first outer spacer is formed on a sidewall of the first inner spacer, and a second outer spacer is formed on a sidewall of the second inner spacer. An erase gate is formed between the first outer spacer and the second outer spacer. The erase gate has a same width, and the erase gate is disconnected between two adjacent bit lines.

In some embodiments, forming the first outer spacer on the sidewall of the first inner spacer includes forming the first outer spacer only above the first floating gate; or forming the first outer spacer above the first floating gate and on two sides of the first floating gate; or forming the first outer spacer only above the first floating gate on one side of the first memory stack, and forming the first outer spacer above the first floating gate and on one side of the first floating gate on other side of the first memory stack.

In some embodiments, forming the second outer spacer on the sidewall of the second inner spacer includes forming the second outer spacer only above the second floating gate; or forming the second outer spacer above the second floating gate and on two sides of the second floating gate; or forming the second outer spacer only above the second floating gate on one side of the second memory stack, and forming the second outer spacer above the second floating gate and on one side of the second floating gate on other side of the second memory stack.

In some embodiments, the first inner spacer is silicon oxide or silicon oxide-silicon nitride-silicon oxide.

In some embodiments, the first outer spacer is a high temperature oxide.

In some embodiments, the second inner spacer is silicon oxide or silicon oxide-silicon nitride-silicon oxide.

In some embodiments, the second outer spacer is a high temperature oxide.

Based on the above, the disclosure provides the cell structure of the third generation embedded super flash memory and the method of forming the same. By the presence of the erase gate with the same width and the characteristic of the erase gate being disconnected between the two adjacent bit lines, defects may be more easily and accurately located to improve the capability and reliability of failure analysis (FA).

In order for the features and advantages of the disclosure to be more comprehensible, the following specific embodiments are described in detail in conjunction with the drawings.

### BRIEF DESCRIPTION OF THE DRAWINGS

FIG. 1 is a cross-sectional schematic diagram of a cell structure of a third generation embedded super flash memory according to an embodiment of the disclosure.

FIG. 2 is a partial circuit diagram of a third generation embedded super flash memory according to an embodiment of the disclosure.

FIG. 3A and FIG. 3B are cross-sectional schematic diagrams of a method of forming a cell structure of a third generation embedded super flash memory according to an embodiment of the disclosure.

### DESCRIPTION OF THE EMBODIMENTS

The following lists embodiments to be described in detail with reference to the drawings, but the embodiments provided are not intended to limit the scope of the disclosure. In addition, the drawings are for illustration purposes only and are not drawn to scale. Also, for the sake of easy understanding, the same elements will be indicated by the same numerals, which will not be reiterated one by one in the following paragraphs.

Terms such as “contain”, “include”, and “have” used herein are open-ended terms, which mean “containing but not limited to”.

In addition, directional terms mentioned herein, such as “upper”, “lower”, “top”, and “bottom”, are only used to refer to the directions of the drawings and are not used to limit the disclosure. Therefore, it should be understood that “upper” may be used interchangeably with “lower”, and “top” may be used interchangeably with “bottom”. Also, when an element such as a layer or a film is placed “on” another element, the element may be directly placed on the other element or there may be an intermediate element. On the other hand, when an element is referred to as being placed “directly on” another element, there is no intermediate element between the two.

As used herein, “about”, “approximately”, or “substantially” includes the stated value and the mean within an acceptable range of deviation of the particular value that can be determined by one of ordinary skill in the art, taking into account the measurement in discussion and the particular amount of error associated with the measurement (that is, limitations of a measurement system). For example, “about” may represent being within one or more standard deviations or within ±30%, ±20%, ±10%, or ±5% of the stated value. Furthermore, the terms “about”, “approximately”, or “substantially” used herein may be used to select a more acceptable deviation range or standard deviation according to optical properties, etching properties, or other properties, and one standard deviation may not apply to all properties.

The terms used herein are only for describing exemplary embodiments and are not intended to be limiting of the disclosure. In this case, the singular form includes the plural form unless otherwise explained in the context.

The various formation steps described below include a deposition process, a removal process, a patterning process, etc.

The deposition process refers to the process of forming a material on another material and may include techniques such as spin coating, sputtering, chemical vapor deposition (CVD), physical vapor deposition (PVD), plasma enhanced chemical vapor deposition (PE-CVD), atomic layer deposition (ALD), molecular beam deposition (MBD), pulsed laser deposition (PLD), and liquid source misted chemical deposition (LSMCD), but not limited thereto.

The removal process may include wet etching, dry etching, chemical mechanical planarization (CMP), etc., but not limited thereto.

The patterning process may include coating a photoresist according to a desired pattern, then enabling the photoresist to react by exposure, performing exposure and development steps to pattern the photoresist, transferring the photoresist shape to a material by etching, removing the material that needs to be removed and the photoresist, and finally performing steps such as cleaning, but not limited thereto.

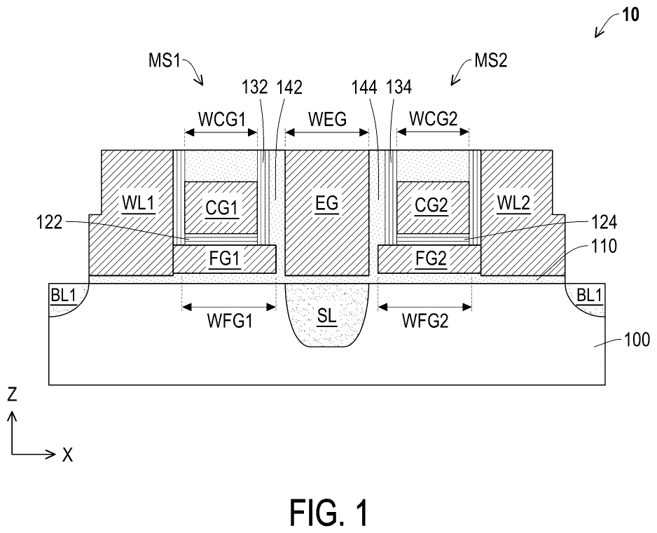

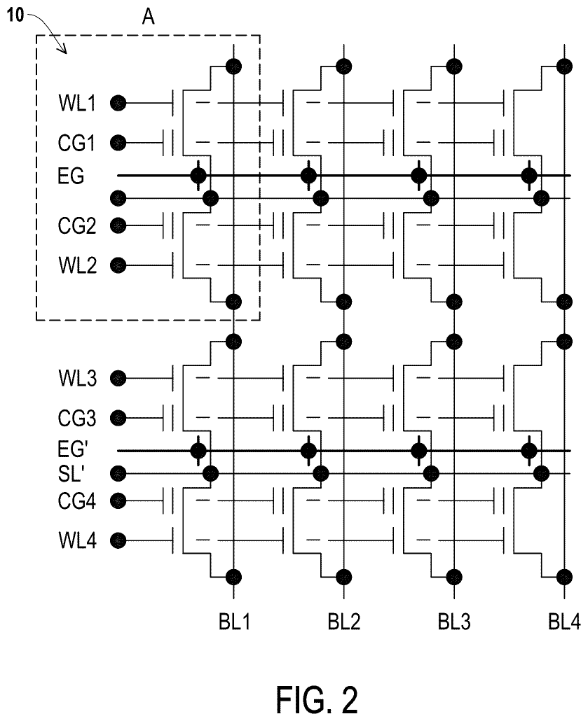

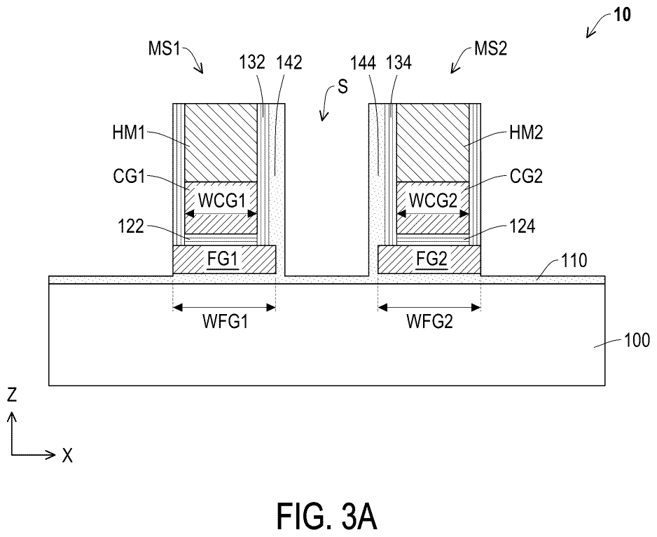

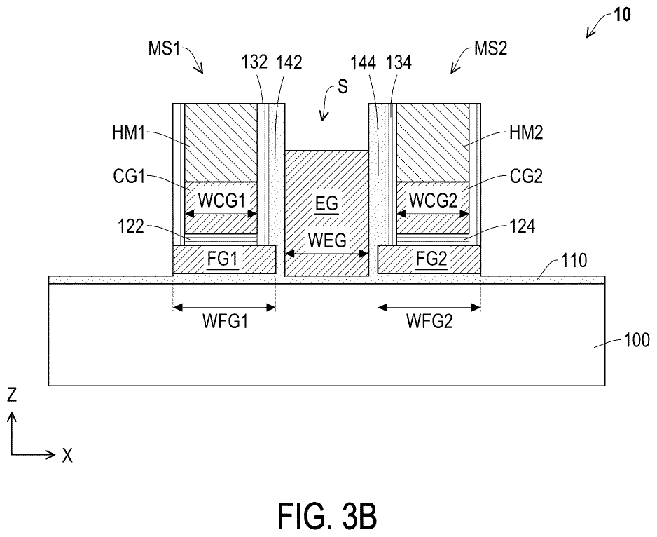

For a cell structure of a third generation embedded super flash memory of the disclosure and a method of forming the same, please refer to the following embodiments, in conjunction with the cross-sectional schematic diagram of the cell structure of the third generation embedded super flash memory of FIG. 1, the partial circuit diagram of the third generation embedded super flash memory of FIG. 2, and the cross-sectional schematic diagrams of the method of forming the cell structure of the third generation embedded super flash memory of FIG. 3A and FIG. 3B. Furthermore, the drawings are for illustration purposes only and are not intended to limit the scope of the disclosure.

First, please refer to a cell structure 10 of the third generation embedded super flash memory shown in FIG. 1, including a source line SL located in a substrate 100; and a first memory stack MS1, a second memory stack MS2, and an erase gate EG located above the substrate 100. The first memory stack MS1 includes a first floating gate FG1 and a first control gate CG1 located above the first floating gate FG1. The second memory stack MS2 includes a second floating gate FG2 and a second control gate CG2 located above the second floating gate FG2. The erase gate EG is located between the first memory stack MS1 and the second memory stack MS2, and is located above the source line SL, wherein the erase gate EG has the same width WEG in a first horizontal direction X, and the erase gate EG is disconnected between two adjacent bit lines. For example, as shown in FIG. 2, the erase gate EG is disconnected between two adjacent bit lines BL1 and BL2.

In some embodiments, as shown in FIG. 1, a width WFG1 of the first floating gate FG1 in the first horizontal direction X may be greater than a width WCG1 of the first control gate CG1 in the first horizontal direction X; and a width WFG2 of the second floating gate FG2 in the first horizontal direction X may be greater than a width WCG2 of the second control gate CG2 in the first horizontal direction X.

In some embodiments, as shown in FIG. 1, the first memory stack MS1 further includes a first inter-gate dielectric layer 122 between the first floating gate FG1 and the first control gate CG1; and the second memory stack MS2 further includes a second inter-gate dielectric layer 124 between the second floating gate FG2 and the second control gate CG2.

In some embodiments, the first inter-gate dielectric layer 122 and the second inter-gate dielectric layer 124 may respectively include a single dielectric layer, such as a single silicon oxide layer, but not limited thereto. In some embodiments, the first inter-gate dielectric layer 122 and the second inter-gate dielectric layer 124 may respectively include multiple dielectric layers, such as silicon oxide-silicon nitride-silicon oxide (ONO) layers, as shown in FIG. 1, but not limited thereto.

Please continue to refer to FIG. 1. The cell structure 10 of the third generation embedded super flash memory further includes a first inner spacer 132 and a first outer spacer 142 on sidewalls of the first memory stack MS1. The first inner spacer 132 may include a dielectric material such as silicon oxide or silicon oxide-silicon nitride-silicon oxide (ONO), but not limited thereto. The first outer spacer 142 may include an insulating material such as high temperature oxide (HTO), but not limited thereto.

In some embodiments, the first outer spacer 142 may be formed on two sidewalls of the first inner spacer 132 on two sides of the first memory stack MS1. Alternatively, the first outer spacer 142 may be formed only on one sidewall of the first inner spacer 132 on one side of the first memory stack MS1 adjacent to the erase gate EG, as shown in FIG. 1.

Please continue to refer to FIG. 1. The cell structure 10 of the third generation embedded super flash memory further includes a second inner spacer 134 and a second outer spacer 144 on sidewalls of the second memory stack MS2. The second inner spacer 134 may include a dielectric material such as silicon oxide or silicon oxide-silicon nitride-silicon oxide (ONO), but not limited thereto. The second outer spacer 144 may include an insulating material such as high temperature oxide (HTO), but not limited thereto.

In some embodiments, the second outer spacer 144 may be formed on two sidewalls of the second inner spacer 134 on two sides of the second memory stack MS2. Alternatively, the second outer spacer 144 may be formed only on one sidewall of the second inner spacer 134 on one side of the second memory stack MS2 adjacent to the erase gate EG, as shown in FIG. 1.

Please continue to refer to FIG. 1. The cell structure 10 of the third generation embedded super flash memory further includes a first word line WL1 and a second word line WL2 located above the substrate 100, wherein the first word line WL1 is between the first memory stack MS1 and the bit line BL1, and the second word line WL2 is between the second memory stack MS2 and the bit line BL1.

Please continue to refer to FIG. 1. The cell structure 10 of the third generation embedded super flash memory further includes a first dielectric layer 110 on the substrate 100 and located below the first word line WL1, the first floating gate FG1, the erase gate EG, the second floating gate FG2, and the second word line WL2. In addition, the first dielectric layer 110 may have the same or different thicknesses at different locations according to element design requirements. For example, the first dielectric layer 110 between the first word line WL1 and the substrate 100 may be thinner than the first dielectric layer 110 between the first floating gate FG1 and the substrate 100, but not limited thereto.

In some embodiments, the first dielectric layer 110 may include a dielectric material such as silicon oxide, but not limited thereto.

Next, please refer to the partial circuit diagram of the third generation embedded super flash memory shown in FIG. 2, wherein the partial circuit diagram of the third generation embedded super flash memory marked by a box A corresponds to the cell structure 10 of the third generation embedded super flash memory shown in FIG. 1.

As shown in FIG. 1 and FIG. 2, the cell structure 10 of the third generation embedded super flash memory is in electrical contact with the bit line BL1 along the first horizontal direction X. Also, as shown in FIG. 2, in another horizontal direction different from the first horizontal direction X, the first word line WL1, the first control gate CG1, the erase gate EG, the source line SL, the second control gate CG2, and the second word line WL2 may be in electrical contact with multiple other bit lines BL2, BL3, BL4, etc., but not limited thereto.

Also, as shown in FIG. 2, a structure similar to the cell structure 10 of the third generation embedded super flash memory may also be included and includes a third word line WL3, a third control gate CG3, an erase gate EG′, a source line SL′, a fourth control gate CG4, and a fourth word line WL4 in electrical contact with the bit lines BL1, BL2, BL3, BL4, etc., but not limited thereto.

In a conventional cell structure of a third generation embedded super flash memory, a erase gate has a shape of being wide at the top and narrow at the bottom. In other words, the width of the erase gate near a substrate portion is less than the width away from the substrate portion. In other words, the width of the erase gate between two adjacent floating gates is less than the width of the erase gate between two adjacent control gates.

However, in the disclosure, the erase gate EG has approximately the same width WEG. In other words, the width of the erase gate EG of the disclosure near the substrate 100 portion is approximately the same as the width away from the substrate 100 portion. In other words, the width of the erase gate EG between the two adjacent floating gates FG1 and FG2 of the disclosure is approximately the same as the width of the erase gate EG between the two adjacent control gates CG1 and CG2.

The erase gate having the shape of being wide at the top and narrow at the bottom often shows sudden changes at where the width changes. However, the erase gate EG of the disclosure has approximately the same width WEG. Even if the width WEG of the erase gate EG has slight differences due to process factors, the erase gate EG still has a smooth profile without any sudden width change.

Furthermore, compared with the prior art, the erase gate EG of the disclosure lacks an upper bump, which represents that the erase gate EG originally connected between two adjacent bit lines is disconnected.

In the prior art, two adjacent bit lines share one erase gate. For example, in FIG. 2, the two adjacent bit lines BL1 and BL2 share one erase gate EG in the conventional third generation embedded super flash memory. Also, the erase gates of each bit in adjacent word lines are connected to each other. For example, in FIG. 2, the erase gates EG of each bit in the adjacent word lines BL1, BL2, BL3, and BL4 are connected to each other. Therefore, if an erase voltage of a certain bit is abnormal, the erase voltage of each bit in the adjacent word line will also become abnormal.

However, in the disclosure, the erase gate EG is disconnected between the two adjacent bit lines. As shown in FIG. 2, the erase gate EG is disconnected between the bit line BL1 and the bit line BL2, the erase gate EG is disconnected between the bit line BL2 and the bit line BL3, the erase gate EG is disconnected between the bit line BL3 and the bit line BL4, etc. Therefore, if the erase voltage of a certain bit is abnormal, the specific location of the fault may be accurately determined, simplifying failure analysis (FA) to improve the capability and reliability of failure analysis (FA).

Next, please refer to FIG. 3A and FIG. 3B, which are cross-sectional schematic diagrams of a method of forming a cell structure of a third generation embedded super flash memory according to an embodiment of the disclosure, wherein the same components as those of the cell structure 10 of the third generation embedded super flash memory of FIG. 1 are denoted by the same numerals.

First, please refer to FIG. 3A. The first memory stack MS1 and the second memory stack MS2 may be formed above the substrate 100 using manners such as deposition, lithography, and etching. The first memory stack MS1 sequentially includes the first floating gate FG1, the first inter-gate dielectric layer 122, the first control gate CG1, and a first hard mask HM1 in a vertical direction Z, wherein the width WFG1 of the first floating gate FG1 in the first horizontal direction X perpendicular to the vertical direction Z is greater than the width WCG1 of the first inter-gate dielectric layer 122, the first control gate CG1, and the first hard mask HM1 in the first horizontal direction X. The second memory stack MS2 sequentially includes the second floating gate FG2, the second inter-gate dielectric layer 124, the second control gate CG2, and a second hard mask HM2 in the vertical direction Z, wherein the width WFG2 of the second floating gate FG2 in the first horizontal direction X perpendicular to the vertical direction Z is greater than the width WCG2 of the second inter-gate dielectric layer 124, the second control gate CG2, and the second hard mask HM2 in the first horizontal direction X.

Please continue to refer to FIG. 3A. The substrate 100 further includes the first dielectric layer 110, and the first dielectric layer 110 is located below the first memory stack MS1 and the second memory stack MS2. In addition, the first dielectric layer 110 may have the same or different thicknesses at different locations according to element design requirements, but not limited thereto. In addition, the first dielectric layer 110 may include a dielectric material such as silicon oxide, but not limited thereto.

Next, please still refer to FIG. 3A. The first inner spacer 132 is respectively formed on sidewalls of the first inter-gate dielectric layer 122, the first control gate CG1, and the first hard mask HM1, and the second inner spacer 134 is respectively formed on sidewalls of the second inter-gate dielectric layer 124, the second control gate CG2, and the second hard mask HM2.

Next, please still refer to FIG. 3A. The first outer spacer 142 is formed on a sidewall of the first inner spacer 132, and the second outer spacer 144 is formed on a sidewall of the second inner spacer 134.

Since the width WFG1 of the first floating gate FG1 in the first horizontal direction X is greater than the width WCG1 of the first inter-gate dielectric layer 122, the first control gate CG1, and the first hard mask HM1 in the first horizontal direction X, the first outer spacer 142 may be formed only above the first floating gate FG1. Alternatively, the first outer spacer 142 may be formed above the first floating gate FG1 and formed on two sides of the first floating gate FG1. Alternatively, on one side of the first memory stack MS1, the first outer spacer 142 may be formed only above the first floating gate FG1, and on the other side of the first memory stack MS1, the first outer spacer 142 is formed above the first floating gate FG1 and formed on one side of the first floating gate FG1, as shown in FIG. 3A.

In addition, the first outer spacer 142 may be formed only on a sidewall of the first memory stack MS1 in a region S, as shown in FIG. 3A, or the first outer spacer 142 may be formed on two sides of the first memory stack MS1.

Furthermore, since the width WFG2 of the second floating gate FG2 in the first horizontal direction X is greater than the width WCG2 of the second inter-gate dielectric layer 124, the second control gate CG2, and the second hard mask HM2 in the first horizontal direction X, the second outer spacer 144 may be formed only above the second floating gate FG2. Alternatively, the second outer spacer 144 may be formed above the second floating gate FG2 and formed on two sides of the second floating gate FG2. Alternatively, on one side of the second memory stack MS2, the second outer spacer 144 may be formed only above the second floating gate FG2, and on the other side of the second memory stack MS2, the second outer spacer 144 is formed above the second floating gate FG2 and formed on one side of the second floating gate FG2, as shown in FIG. 3A.

In addition, the second outer spacer 144 may be formed only on a sidewall of the second memory stack MS2 in the region S, as shown in FIG. 3A, or the second outer spacer 144 may be formed on two sides of the second memory stack MS2.

Next, please refer to FIG. 3B. The erase gate EG is formed between the first outer spacer 142 and the second outer spacer 144. Furthermore, due to the presence of the first inner spacer 132, the first outer spacer 142, the second inner spacer 134, and the second outer spacer 144, even if the width WFG1 of the first floating gate FG1 in the first horizontal direction X is greater than the first inter-gate dielectric layer 122 and the width WFG2 of the second floating gate FG2 in the first horizontal direction X is greater than the second inter-gate dielectric layer 124, the erase gate EG formed in the region S may have approximately the same width WEG, as shown in FIG. 3B.

In other words, in the method of forming the cell structure of the third generation embedded super flash memory of the disclosure, the first outer spacer 142 and the second outer spacer 144 that are removed in the original process are retained, so that the erase gate that is originally formed to be wide at the top and narrow at the bottom becomes rectangular with approximately the same width at the top and the bottom, and the new shape of the erase gate EG enables the erase gate EG that is originally connected to each other between multiple cell structures to be disconnected, so that defects may be more easily and accurately located, simplifying failure analysis (FA) to improve the capability and reliability of failure analysis (FA).

Next, in some embodiments, various etching processes may be used to remove the first hard mask HM1 and the second hard mask HM2, and various dielectric materials, silicon oxide, etc. may be deposited. Then, full planarization may be performed by manners such as chemical mechanical polishing (CMP) to form the cell structure 10 of the third generation embedded super flash memory as shown in FIG. 1.

In addition to the cross-sectional schematic diagrams of the method of forming the cell structure of the third generation embedded super flash memory shown in FIG. 3A and FIG. 3B, various semiconductor processes may be used to form the source line SL and the bit line BL in the substrate 100 and to form the first word line WL1 and the second word line WL2 above the substrate 100, as shown in FIG. 1. The formation manner and the formation sequence are not particularly limited, and any technique that may form the third generation embedded super flash memory may be applied to the disclosure.

In view of the above, the disclosure provides the cell structure of the third generation embedded super flash memory and the method of forming the same. By the presence of the erase gate with the same width and the characteristic of the erase gate being disconnected between the two adjacent bit lines, defects may be more easily and accurately located to improve the capability and reliability of failure analysis (FA).

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A cell structure of a third generation embedded super flash memory, comprising:
a source line, located in a substrate; and
a first memory stack, a second memory stack, and an erase gate, located above the substrate, wherein:
the first memory stack comprises a first floating gate and a first control gate located above the first floating gate,
the second memory stack comprises a second floating gate and a second control gate located above the second floating gate, and
the erase gate is located between the first memory stack and the second memory stack and is located above the source line, wherein the erase gate has a same width in a first horizontal direction, and the erase gate is disconnected between two adjacent bit lines.

2. The cell structure of the third generation embedded super flash memory according to claim 1, wherein a width of the first floating gate in the first horizontal direction is greater than a width of the first control gate in the first horizontal direction.

3. The cell structure of the third generation embedded super flash memory according to claim 1, wherein a width of the second floating gate in the first horizontal direction is greater than a width of the second control gate in the first horizontal direction.

4. The cell structure of the third generation embedded super flash memory according to claim 1, wherein the first memory stack further comprises a first inter-gate dielectric layer between the first floating gate and the first control gate.

5. The cell structure of the third generation embedded super flash memory according to claim 1, wherein the second memory stack further comprises a second inter-gate dielectric layer between the second floating gate and the second control gate.

6. The cell structure of the third generation embedded super flash memory according to claim 1, further comprising a first inner spacer and a first outer spacer on a sidewall of the first memory stack.

7. The cell structure of the third generation embedded super flash memory according to claim 6, wherein the first inner spacer is silicon oxide or silicon oxide-silicon nitride-silicon oxide.

8. The cell structure of the third generation embedded super flash memory according to claim 6, wherein the first outer spacer is a high temperature oxide.

9. The cell structure of the third generation embedded super flash memory according to claim 1, further comprising a second inner spacer and a second outer spacer on a sidewall of the second memory stack.

10. The cell structure of the third generation embedded super flash memory according to claim 9, wherein the second inner spacer is silicon oxide or silicon oxide-silicon nitride-silicon oxide.

11. The cell structure of the third generation embedded super flash memory according to claim 9, wherein the second outer spacer is a high temperature oxide.

12. The cell structure of the third generation embedded super flash memory according to claim 1, further comprising:
a first word line and a second word line, located above the substrate, wherein:
the first word line is between the first memory stack and the bit line, and
the second word line is between the second memory stack and the bit line.

13. A method of forming a cell structure of a third generation embedded super flash memory, comprising:
forming a first memory stack and a second memory stack above a substrate, wherein:
the first memory stack sequentially comprises a first floating gate, a first inter-gate dielectric layer, a first control gate, and a first hard mask in a vertical direction, wherein a width of the first floating gate in a first horizontal direction perpendicular to the vertical direction is greater than a width of the first inter-gate dielectric layer, the first control gate, and the first hard mask in the first horizontal direction, and
the second memory stack sequentially comprises a second floating gate, a second inter-gate dielectric layer, a second control gate, and a second hard mask in the vertical direction, wherein a width of the second floating gate in the first horizontal direction perpendicular to the vertical direction is greater than a width of the second inter-gate dielectric layer, the second control gate, and the second hard mask in the first horizontal direction;
respectively forming a first inner spacer on sidewalls of the first inter-gate dielectric layer, the first control gate, and the first hard mask, and a second inner spacer on sidewalls of the second inter-gate dielectric layer, the second control gate, and the second hard mask;
forming a first outer spacer on a sidewall of the first inner spacer, and forming a second outer spacer on a sidewall of the second inner spacer; and
forming an erase gate between the first outer spacer and the second outer spacer, wherein the erase gate has a same width, and the erase gate is disconnected between two adjacent bit lines.

14. The method of forming the cell structure of the third generation embedded super flash memory according to claim 13, wherein forming the first outer spacer on the sidewall of the first inner spacer comprises:
forming the first outer spacer only above the first floating gate; or
forming the first outer spacer above the first floating gate and on two sides of the first floating gate; or
forming the first outer spacer only above the first floating gate on one side of the first memory stack, and forming the first outer spacer above the first floating gate and on one side of the first floating gate on other side of the first memory stack.

15. The method of forming the cell structure of the third generation embedded super flash memory according to claim 13, wherein forming the second outer spacer on the sidewall of the second inner spacer comprises:
forming the second outer spacer only above the second floating gate; or
forming the second outer spacer above the second floating gate and on two sides of the second floating gate; or
forming the second outer spacer only above the second floating gate on one side of the second memory stack, and forming the second outer spacer above the second floating gate and on one side of the second floating gate on other side of the second memory stack.

16. The method of forming the cell structure of the third generation embedded super flash memory according to claim 13, wherein the first inner spacer is silicon oxide or silicon oxide-silicon nitride-silicon oxide.

17. The method of forming the cell structure of the third generation embedded super flash memory according to claim 13, wherein the first outer spacer is a high temperature oxide.

18. The method of forming the cell structure of the third generation embedded super flash memory according to claim 13, wherein the second inner spacer is silicon oxide or silicon oxide-silicon nitride-silicon oxide.

19. The method of forming the cell structure of the third generation embedded super flash memory according to claim 13, wherein the second outer spacer is a high temperature oxide.
